(19) United States
(12) Patent Application Publication
(10) Pub. No.: US 2015/0214079 A1
(43) Pub. Date: Jul. 30, 2015

(54) WET STATION

(71) Applicant: SAMSUNG ELECTRONICS CO., LTD., Suwon-si (KR)

(72) Inventors: Dae Hong EOM, Hwaseong-si (KR); Kyung Hyun KIM, Seoul (KR); Hyun Ho SON, Hwaseong-si (KR)

(21) Appl. No.: 14/323,154

(22) Filed: Jul. 3, 2014

(30) Foreign Application Priority Data
Jan. 24, 2014 (KR) 10-2014-0008916

(51) Int. Cl. H01L 21/67; H01L 21/677; H01L 21/673

(52) U.S. Cl. CPC H01L 21/67057; H01L 21/6735; H01L 21/67742; H01L 21/67748; H01L 21/67023

(57) ABSTRACT

There is provided a wet station including: a loading unit to and from which a front open unified pod (FOUP) in which semiconductor wafers are installed and a stocker in which dummy wafers are installed are loaded and unloaded; a wafer transferring robot removing the semiconductor wafers from the loaded FOUP and loading the semiconductor wafers into a wafer guide; a dummy transferring robot removing the dummy wafers from the loaded stocker and loading the dummy wafers into empty slots of the wafer guide in which the semiconductor wafers have not been loaded; and a processing chamber receiving the wafer guide fully loaded with the semiconductor wafers and the dummy wafers and performing a cleaning process on the semiconductor wafers.

### CROSS-REFERENCE TO RELATED APPLICATION

This application claims the benefit of Korean Patent Application No. 10-2014-0008916 filed on Jan. 24, 2014, with the Korean Intellectual Property Office, the disclosure of which is incorporated herein by reference.

### BACKGROUND

The present disclosure relates to a wet station (or a wet cleaning apparatus).

In general, pure silicon wafer is manufactured to be a single complete semiconductor device by repeatedly performing an array of unit processes such as a photolithography process, an etching process, a thin film deposition process, an ion implantation process, a metal wiring process, and the like, thereon. Patterns of semiconductor devices manufactured through these processes have increasingly become microfine and highly integrated, thus complicating the processes. In particular, a wet cleaning process may be performed in a bath provided with an etching solution, and uniformity of processes applied to introduced wafers needs to be secured. Also, selectivity with respect to a particular material among multiple materials needs to be improved.

### SUMMARY

An aspect of the present disclosure may provide a method for enhancing uniformity of wafers by maintaining a uniform etching rate regardless of an amount of wafers to be cleaned, and increasing etching selectivity.

However, aspects of the present disclosure are not limited thereto and aspects and effects that may be recognized from technical solutions or embodiments described hereinafter may also be included although not explicitly mentioned.

According to an aspect of the present disclosure, a wet station may include a loading unit to and from which a front open unified pod (FOUP) in which semiconductor wafers are installed and a stocker in which dummy wafers are installed are loaded and unloaded; a wafer transferring robot removing the semiconductor wafers from the loaded FOUP and loading the semiconductor wafers into a wafer guide; a dummy transferring robot removing the dummy wafers from the loaded stocker and loading the dummy wafers into empty slots of the wafer guide in which the semiconductor wafers have not been loaded; and a processing chamber receiving the wafer guide fully loaded with the semiconductor wafers and the dummy wafers and performing a cleaning process on the semiconductor wafers.

The wet station may further include a sensor sensing the semiconductor wafers loaded in the FOUP to determine whether a slot in which a semiconductor wafer is not loaded is present and generating information regarding the slot.

The sensor may transfer the information regarding the empty slot in which the semiconductor wafer is not loaded to the dummy transferring robot to allow the dummy transferring robot to load a dummy wafer into the empty slot of the wafer guide into which the semiconductor wafer has not been loaded.

The wet station may further include a direction adjusting unit adjusting a direction of the semiconductor wafers such that the semiconductor wafers are arranged in a vertical direction with respect to a bottom surface of the wafer guide or the semiconductor wafers reloaded into the FOUP from the wafer guide are arranged in a horizontal direction with respect to the bottom surface of the wafer guide.

The processing chamber may include a bath in which a wet etchant is accommodated and a drying chamber.

The processing chamber may further include a transfer arm transferring the wafer guide to the bath and the drying chamber.

The transfer arm may reciprocate along a wafer transfer line disposed to be adjacent to the bath and the drying chamber.

A plurality of baths may be provided, and may include a chemical bath and a rinsing bath.

The loading unit may include a prop on which the FOUP and the stocker are supportedly placed.

The wet station may further include a controller controlling driving of the loading unit, the wafer transferring robot, the dummy transferring robot, and the processing chamber.

The wafer transferring robot may reload the plurality of semiconductor wafers having completely undergone the cleaning process from the wafer guide to the FOUP.

The dummy transferring robot may reload the dummy wafers which have been completely undergone the cleaning process from the wafer guide to the stocker.

According to another aspect of the present disclosure, a wet station may include: a wafer transferring robot removing semiconductor wafers from a front open unified pod (FOUP) in which the semiconductor wafers are installed and loading the semiconductor wafers into a wafer guide; a dummy transferring robot removing dummy wafers from a stocker in which the dummy wafers are installed and loading the dummy wafers into empty slots to which the semiconductor wafers have not been loaded; and a controller controlling operations of the wafer transferring robot and the dummy transferring robot by sensing the semiconductor wafers loaded in the FOUP by means of a sensor.

The sensor may transfer information regarding empty slots to which the semiconductor wafers have not been loaded to the dummy transferring robot to allow the dummy transferring robot to load the dummy wafers into the empty slots of the wafer guide to which the semiconductor wafers have not been loaded.

The wet station may further include a processing chamber receiving the wafer guide fully loaded with the semiconductor wafers and the dummy wafers and performing a cleaning process on the semiconductor wafers.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view schematically illustrating a wet station according to an example embodiment of the present disclosure;

FIGS. 2A and 2B are a perspective view and a front view schematically illustrating a FOUP in which semiconductor wafers are loaded and a sensor mapping the same;

FIG. 3 is a front view schematically illustrating a direction adjusting unit;

FIGS. 4A and 4B are side views schematically illustrating an operational principle of the direction adjusting unit of FIG. 3;

FIGS. 5 and 6 are a plan view and a side view schematically illustrating a structure in which a semiconductor wafer and a dummy wafer are loaded on a wafer guide in FIG. 1;

FIG. 7A is a cross-sectional view schematically illustrating semiconductor wafers for manufacturing a semiconductor device;

FIG. 7B is a cross-sectional view schematically illustrating a state in which a first layer is selectively removed from a laminate including first and second layers in FIG. 7A;

FIG. 8 is a plan view schematically illustrating a wet station according to another example embodiment of the present disclosure; and

FIG. 9 is a flow chart schematically illustrating a wet cleaning process according to an example embodiment of the present disclosure.

### DETAILED DESCRIPTION

Hereinafter, example embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

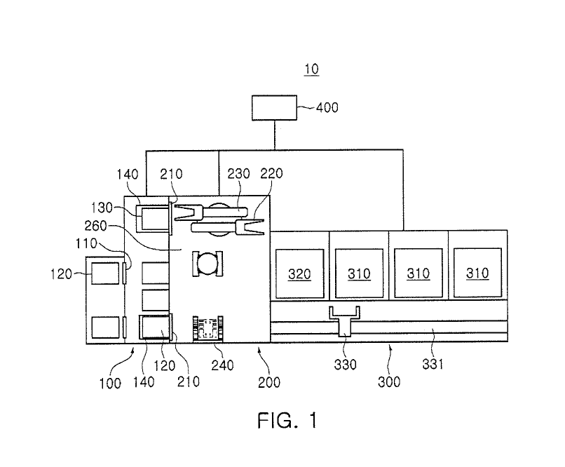

A wet station 10 according to an example embodiment of the present disclosure will be described with reference to FIG. 1. FIG. 1 is a plan view schematically illustrating a wet station according to an example embodiment of the present disclosure.

Referring to FIG. 1, the wet station 10 according to an example embodiment of the present disclosure may include a loading unit 100, a wafer transferring robot 220, a dummy transferring robot 230, and a processing chamber 300.

A plurality of semiconductor wafers Wf may be loaded to the interior of the loading unit 100 through a load port 110 to undergo a cleaning or wet etching process. The plurality of semiconductor wafers Wf may be loaded in a front open unified pod (FOUP) 120 and transferred. The FOUP 120, a type of pod as a closed-type wafer storage vessel, is a cassette-integrated vessel with an open front side largely used for a wafer having a size of 300 mm or greater. Approximately 25 sheets of semiconductor wafer Wf may be loaded in the FOUP 120.

One or more FOUPs 120 may be loaded into the interior of the loading unit 100 corresponding to a buffer region.

A stocker 130 in which dummy wafers Wd are installed may be further loaded into the loading unit 100. The stocker 130 may be loaded separately or together with the FOUP 120.

The dummy wafers Wf may be wafers on which a material identical to a material to be etched is deposited. For example, a silicon (Si) wafer, a silicon wafer with a silicon nitride (SiN) deposited thereon, a silicon wafer with silicon oxynitride (SiON) deposited thereon, or the like, may be used as the dummy wafers Wd.

A prop 140 may be provided in the loading unit 100. The FOUP 120 and the stocker 130 may be placed on the prop 140. The prop 140 may fix the FOUP 120, as well as the stocker 130 placed thereon, and transfer the FOUP 120 and the stocker 130 to a loading position.

A docking unit 200 may be provided on one side of the loading unit 100. The docking unit 200 may be connected to the loading unit 100 through a door 210 provided between the docking unit 200 and the loading unit 100. The door 210 may be, for example, a front-opening interface mechanical standard (FIMS) door.

The docking unit 200 may include a wafer transferring robot 220, a dummy transferring robot 230, and a wafer guide 240.

The wafer transferring robot 220 may remove the plurality of semiconductor wafers Wf loaded in the FOUP 120, and load the same in the wafer guide 240, when the door 210 is opened to open a front side of the FOUP 120. Also, conversely, the wafer transferring robot 220 may reload the plurality of semiconductor wafers Wf from the wafer guide 240 into the FOUP 120.

The dummy transferring robot 230 may remove the dummy wafer Wd from the stocker 130 and load the dummy wafer Wd into an empty slot of the wafer guide 240, namely, to a slot in which the semiconductor wafer Wf is not loaded. Also, conversely, the dummy transferring robot 230 may reload the dummy wafer Wd from the wafer guide 240 to the stocker 130.

The wafer transferring robot 220 and the dummy transferring robot 230 may load the plurality of semiconductor wafers Wf and the dummy wafers Wd to accurate positions of the wafer guide 240 based on information transmitted through a sensor 250 provided within the docking unit 200.

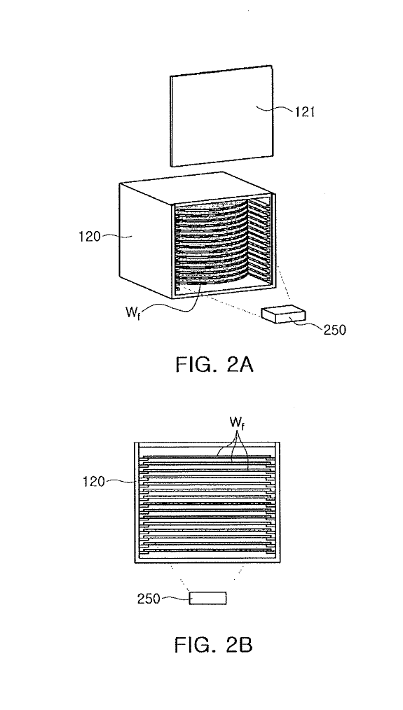

FIGS. 2A and 2B are a perspective view and a front view schematically illustrating a FOUP in which semiconductor wafers are loaded and a sensor mapping the same.

As illustrated in FIGS. 2A and 2B, when a front cover 121 of the FOUP 120 is open together with the door 210, the sensor 250 senses the semiconductor wafers Wf installed in the FOUP 120 and maps the semiconductor wafers Wf. Also, the sensor 250 determines whether a slot in which the semiconductor wafer Wf is not loaded is present, and generates information regarding the slot.

Based on the information regarding slots determined by the sensor 250, the wafer transferring robot 220 removes the plurality of semiconductor wafers Wf from the FOUP 120 and installs the same in the slots of the wafer guide 240. The dummy transferring robot 230 removes a dummy wafer Wd from the stocker 130 and installs the same in an empty slot in which the semiconductor wafer Wf is not installed. In this case, the dummy transferring robot 230 may operate when an empty slot in which the semiconductor wafer Wf is not installed is ascertained. Thus, in a case in which the plurality of semiconductor wafers Wf are fully installed in the slots of the wafer guides 240, there is no need to install the dummy wafer Wd in the wafer guide 240. Namely, the dummy wafer Wd is selectively installed to maintain a predetermined amount of wafers in the wafer guide 240 such that cleaning or wet etching is performed on predetermined capacity.

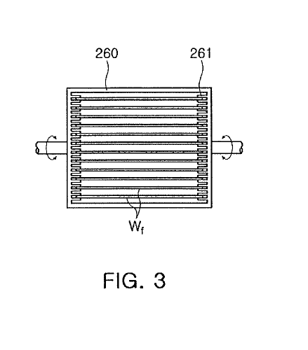

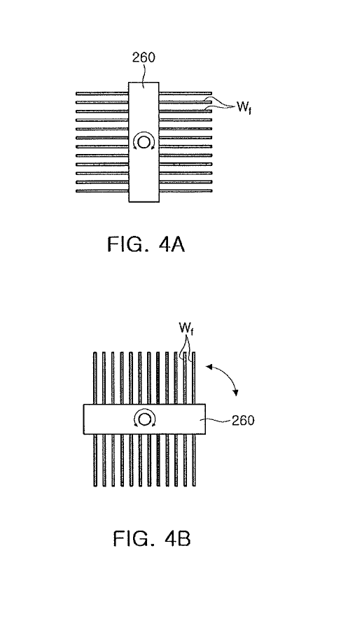

Meanwhile, the docking unit 200 may further include a direction adjusting unit 260. FIGS. 3 and 4 schematically illustrate the direction adjusting unit. As illustrated in FIG. 3, the direction adjusting unit 260 may include a plurality of slots 261 in which the plurality of semiconductor wafers Wf may be installed. The direction adjusting unit 260 adjusts an arrangement direction of the plurality of semiconductor wafers Wf.

As illustrated in FIGS. 4A and 4B, in a state in which the plurality of semiconductor wafers Wf, which have been removed from the FOUP 120, are installed in the slots in a horizontal direction, the direction adjusting unit 260 may rotate the plurality of wafers Wf by 90 degrees to erect them in a vertical direction, thus adjusting an arrangement direction. Thus, the semiconductor wafers Wf installed in the wafer guide 240 may be erected in the vertical direction with respect a bottom surface of the wafer guide 240 so as to be placed in the slots of the wafer guide 240.

Conversely, in order to reload the semiconductor wafers Wf from the wafer guide 240 to the FOUP 120, the direction adjusting unit 260 may adjust the direction of the semiconductor wafers Wf such that they are arranged in a horizontal direction with respect to the bottom surface.

The wafer guide 240 may include a plurality of slots 241 arranged at predetermined gaps. The plurality of semiconductor wafers Wf or the plurality of semiconductor wafers Wf and dummy wafers Wd may be installed in the plurality of slots 241.

The plurality of semiconductor wafers Wf (and the dummy wafer Wd) may be installed in the wafer guide 240 and transferred to the processing chamber 300 to undergo a cleaning and wet etching process.

The processing chamber 300 may be provided on one side of the docking unit 200. The processing chamber 300 may receive the wafer guide 240 fully loaded with the semiconductor wafers Wf and dummy wafers Wd and perform a cleaning or wet etching process on the semiconductor wafers Wf. To this end, the processing chamber 300 may include a plurality of baths 310, a drying chamber 320, and a transfer arm 330 transferring the wafer guide 240 to the plurality of baths 310 and the drying chamber 320.

The plurality of baths 310 may include, for example, a chemical bath, a rinsing bath, a phosphoric acid bath, and the like, and may be disposed in an in-line manner such that the cleaning process may be continuously performed.

A wet etchant accommodated within each bath 310 may be provided in a state in which conditions including a predetermined amount, a concentration, a temperature, and the like, of the wet etchant are set to correspond to respective conditions including an amount, selectivity, and the like, of the semiconductor wafers Wf.

The drying chamber 320 is disposed together with the plurality of baths 310 in an in-line manner, and when the wafer guide 240 which has undergone a final process in the plurality of baths 310 is transferred to the drying chamber 320, a drying process is performed on the semiconductor wafers Wf and the dummy wafers Wd in the drying chamber 320.

The transfer arm 330 reciprocates along a wafer transfer line 331 disposed to be adjacent to the plurality of baths 310 and the drying chamber 320. The transfer arm 330 is selectively fastened to the wafer guide 240 to apply the wafer guide 240 to each bath 310 and discharge the wafer guide 240 from each bath 310 to allow the semiconductor wafers Wf to undergo the cleaning and wet etching process. After the cleaning and wet etching process is finished, the transfer arm 330 transfers the wafer guide 240 to the drying chamber 320 to allow the semiconductor wafers Wf and the dummy wafers Wd within the wafer guide 240 to be dried.

When the cleaning process (including the drying process) performed on the plurality of semiconductor wafers Wf is terminated, the wafer guide 240 is transferred to the docking unit 200 through the transfer arm 330. In the docking unit 200, the wafer transferring robot 220 removes the plurality of cleaned semiconductor wafers Wf from the wafer guide 240 and reloads them into the FOUP 120. The dummy transferring robot 230 removes the dummy wafers Wd from the wafer guide 240 and reloads the dummy wafers Wd into the stocker 130.

The FOUP 120 in which the plurality of cleaned semiconductor wafers Wf is reloaded may be unloaded from the loading unit 100 through the load port 110 and transferred to a next process position.

The loading unit 100, the docking unit 200, and the processing chamber 300 may be independently configured and installed in an in-line manner such that the cleaning process may be successively performed on the semiconductor wafers Wf. The controller 400 may collectively control driving of the loading unit 100, the wafer transferring robot 220 and the dummy transferring robot 230 of the docking unit 200, and the processing chamber 300.

The controller 400 may adjust an amount of the semiconductor wafers Wf and the dummy wafers Wd installed in the wafer guide 240. For example, the controller 400 may adjust a total amount of wafers installed in the wafer guide 240 and an amount of the dummy wafers Wd installed accordingly. Namely, in a case in which a total of 50 sheets of wafer are set to be installed in the wafer guide 240, an amount of the dummy wafers Wd may be defined as a value obtained by subtracting an amount of semiconductor wafers Wf supplied through the FOUP 120 from the total sheets of semiconductor wafers Wf. For example, in a case in which 20 sheets of semiconductor wafers Wf are supplied through the FOUP 120, 30 sheets of dummy wafers Wd may be installed in the empty slots.

The controller 400 may receive information regarding an amount of semiconductor wafers Wf within the FOUP 120 and slots ascertained by the sensor 250, and calculates a required amount of dummy wafers Wd and empty slots to be loaded.

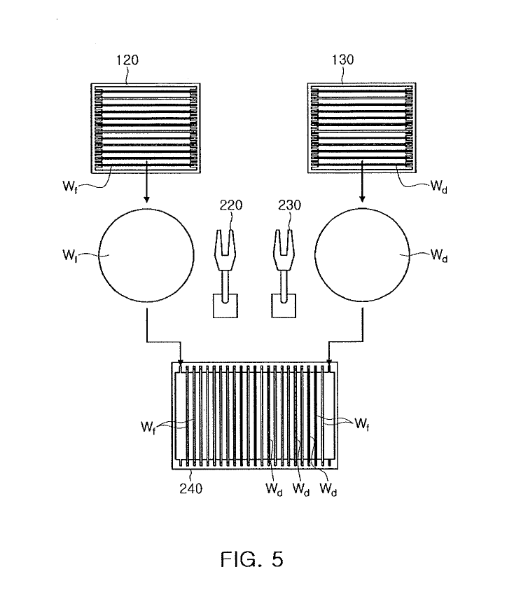

As illustrated in FIGS. 5 and 6, after a plurality of semiconductor wafers Wf are loaded into the wafer guide 240 through the wafer transferring robot 220, the controller 400 drives the dummy transferring robot 230 based on calculated information to load the dummy wafer(s) Wd to a corresponding empty slot(s) to the wafer guide 240.

In this manner, in the wet station 10 according to the present example embodiment, a fixed amount of wafers are always loaded into the wafer guide 240, regardless of the amount of sheets of the semiconductor wafers Wf supplied through the FOUP 120, and a cleaning or wet etching process may be performed thereon.

Since the uniform amount of wafers inserted into the baths 310 is maintained, selectivity between different materials, for example, a nitride and an oxide, is uniformly maintained, thus constantly maintaining a low oxide etching rate. In particular, since the dummy wafers (for example, SiN-deposited silicon wafers) are used, etching selectivity with respect to a nitride may be increased (for example, etching selectivity of nitride:oxide is increased to a level of 200:1 or greater). This is because etching selectivity is increased due byproducts generated as the dummy wafers Wd are etched together. Thus, when a semiconductor device manufactured using semiconductor wafers Wf, since an oxide etching rate is constantly maintained at a low level, uniformity of wafers may be enhanced.

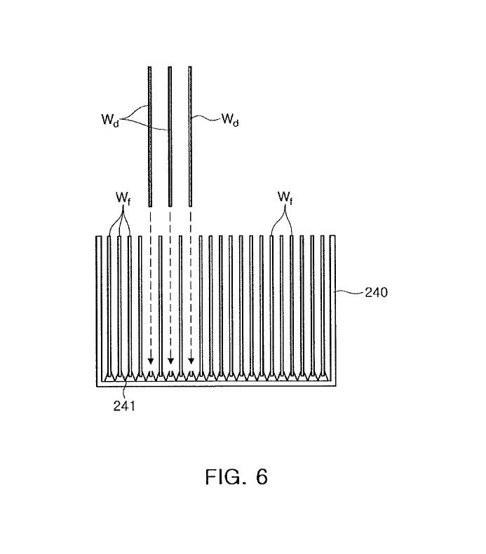

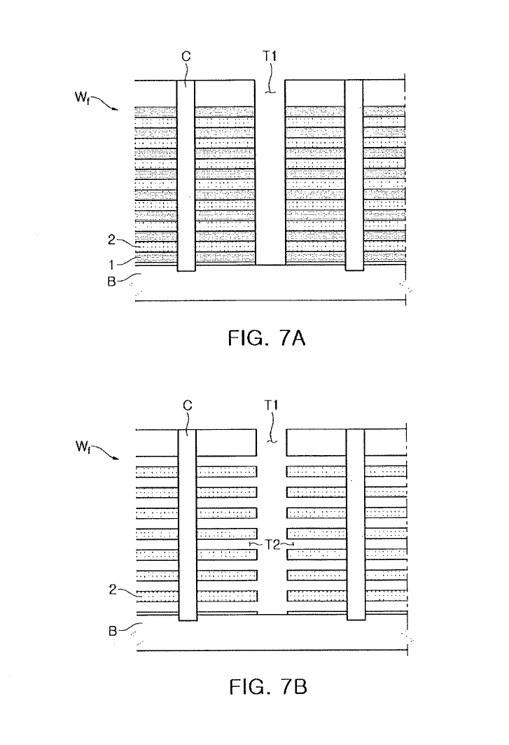

FIG. 7A schematically illustrates semiconductor wafers for manufacturing a semiconductor device. As illustrated in FIG. 7A, the semiconductor device includes a stacked body including alternatively stacked first layers 1 and second layers 2 and an active region formed in a channel hole C penetrating through the stacked body. The stacked body may have a structure in which one side thereof is exposed due to a first opening T1. The semiconductor device may be, for example, a non-volatile memory device having a vertical structure.

FIG. 7B schematically illustrates the stacked body, from which the first layers 1 have been selectively removed by using the aforementioned wet station, having only the second layers 2 left. For example, in a case in which the first layers 1 are silicon nitride layers and the second layers 2 are silicon oxide layers, a wet etchant may include a phosphoric acid. Accordingly, only the first layers 1 may be selectively removed from the stacked body, and selectivity may range, for example, from 100:1 to 200:1. The wet etchant may be introduced into the first opening T1 to consume the first layers 1 and may gradually expand in a horizontal direction, while forming an opening T2.

In this manner, using the wet station according to the example embodiment of the present disclosure, even in the structure including the first and second layers 1 and 2 stacked as multiple layers on a substrate B such as a silicon substrate, only the first layers 1 may be selectively removed effectively.

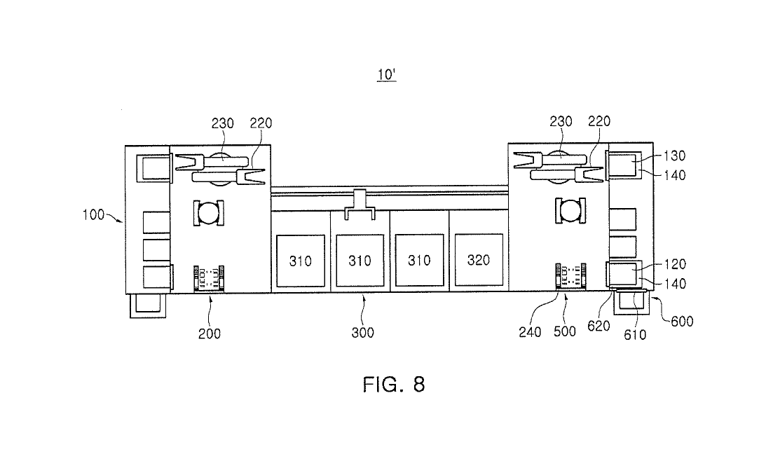

FIG. 8 schematically illustrates a wet station according to another example embodiment of the present disclosure.

The wet station according to the example embodiment illustrated in FIG. 8 include elements substantially identical to those of the example embodiment illustrated in FIG. 1 in a basic structure, except that it further includes a docking unit and a loading unit sequentially provided on the other side of the processing chamber. Thus, hereinafter, redundant descriptions of the same elements as those of the example embodiment described above will be omitted.

FIG. 8 is a plan view schematically illustrating a wet station according to another example embodiment of the present disclosure.

As illustrated in FIG. 8, a wet station 10′ according to the present example embodiment may include a loading unit 100 to which wafers are loaded, a docking unit 200 receiving the loaded wafers from the loading unit 100 and arranging the wafers, a processing chamber 300 receiving the arranged wafers from the docking unit 200 and performing a cleaning or wet etching process thereon, a docking unit 500 receiving the wafers which has completely undergone the cleaning or wet etching process and arranging the wafers, and an unloading unit 600 from which the wafers are unloaded.

In detail, in the wet station 10′ according to the present example embodiment, the loading unit 100, the docking unit 200, the processing chamber 300, the docking unit 500, and the unloading unit 600 are sequentially connected, and the wet station 10′ according to the present example embodiment is different from the wet station 10 according to the example embodiment of FIG. 1, in that the wet station 10′ further includes the docking unit 500 and the unloading unit 600 sequentially connected to one side of the processing chamber 300.

The docking unit 500 may be provided on one side of the processing chamber 300 such that the processing chamber 300 is positioned between the docking unit 500 and the docking unit 200. Like the docking unit 200, the docking unit 500 may include a wafer transferring robot 220 and a dummy transferring robot 230. In addition, the docking unit 500 may selectively include a direction adjusting unit 260. Namely, the docking unit 500 and the docking unit 200 are substantially identical.

After the cleaning process is completed, the wafer guide 240 is transferred to the docking unit 500. The wafer transferring robot 220 of the docking unit 500 removes the plurality of cleaned semiconductor wafers Wf from the wafer guide 240 and reloads the semiconductor wafers Wf to the empty FOUP 120 on standby. Similarly, the dummy transferring robot 230 removes the dummy wafers Wd from the wafer guide 240 and reloads the dummy wafers Wd to the stocker 130.

In this case, in order to allow the semiconductor wafers to be easily loaded to the FOUP 120 and the stocker 130, the direction adjusting unit 260 rotates the plurality of semiconductor wafers Wf and the dummy wafers Wd arranged in a vertically erected state by 90 degrees to adjust an arrangement direction such that the semiconductor wafers Wf and the dummy wafers Wd are in a laid-down state in a horizontal direction.

The unloading unit 600 may be provided on one side of the docking unit 500. The unloading unit 600 may include a prop 620 provided to allow the FOUP 120 to be placed thereon. The prop 620 may fix the FOUP 120 placed thereon and transfer the FOUP 120 to an unloading position. The FOUP 120 in which the plurality of semiconductor wafers Wf, which have completely undergone a wet etching process, are reloaded is unloaded from the unloading unit 600 through an unload port 610 and transferred to a next process position.

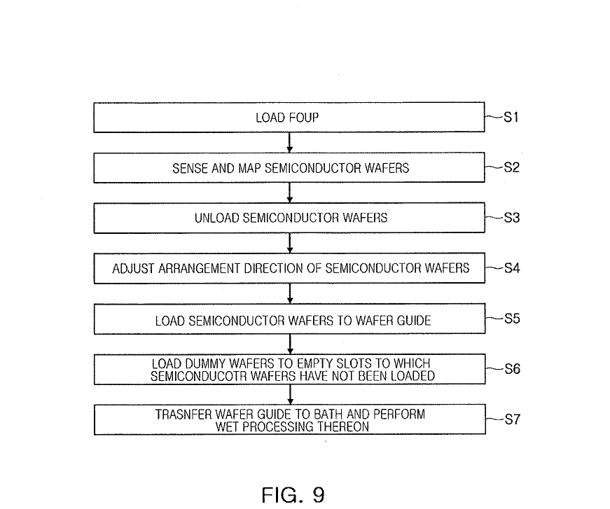

FIG. 9 is a flow chart schematically illustrating a wet cleaning process according to an example embodiment of the present disclosure.

Referring to FIG. 9, first, a FOUP in which a plurality of semiconductor wafers is installed is loaded in operation S1. When a front cover of the FOUP is opened in the loading position, the plurality of semiconductor wafers installed in the FOUP are sensed and mapped through a sensor in operation S2.

When mapping is finished, the plurality of semiconductor wafers is unloaded from the FOUP to the outside through a wafer transferring robot in operation S3.

An arrangement direction of the plurality of unloaded semiconductor wafers is adjusted by a direction adjusting unit in operation S4. The arrangement direction of the semiconductor wafers may be a direction in which the semiconductor wafers are arranged after having been rotated by 90 degrees from a horizontal direction to a vertical direction or from a vertical direction to a horizontal direction.

The plurality of semiconductor wafers adjusted in the arrangement direction are loaded into the wafer guide in operation S5. When an empty slot in which a semiconductor wafer is not installed is present, a dummy wafer is removed from the stocker through a dummy transferring robot and loaded thereto in operation S6.

The wafer guide fully loaded with the semiconductor wafers and the dummy wafers is transferred to baths through a transfer arm and a wetting process (cleaning and wet etching process) is performed on the semiconductor wafers in operation S7.

As set forth above, according to example embodiments of the present disclosure, a wet station capable of enhancing uniformity of wafers and increasing etch selectivity by maintaining a uniform etching rate regardless of an amount of sheets of wafers to be cleaned may be provided.

Advantages and effects of the present disclosure are not limited to the foregoing content and any other technical effects not mentioned herein may be easily understood by a person skilled in the art from the foregoing description.

While example embodiments have been shown and described above, it will be apparent to those skilled in the art that modifications and variations could be made without departing from the spirit and scope of the present disclosure as defined by the appended claims.

What is claimed is:

1. A wet station, comprising:
a loading unit to and from which a front open unified pod (FOUP) in which semiconductor wafers are installed and a stocker in which dummy wafers are installed are loaded and unloaded;
a wafer transferring robot removing the semiconductor wafers from the loaded FOUP and loading the semiconductor wafers into a wafer guide;
a dummy transferring robot removing the dummy wafers from the loaded stocker and loading the dummy wafers into empty slots of the wafer guide in which the semiconductor wafers have not been loaded; and
a processing chamber receiving the wafer guide fully loaded with the semiconductor wafers and the dummy wafers and performing a cleaning process on the semiconductor wafers.

2. The wet station of claim 1, further comprising a sensor sensing the semiconductor wafers loaded in the FOUP to determine whether a slot in which a semiconductor wafer is not loaded is present and generating information regarding the slot.

3. The wet station of claim 2, wherein the sensor transfers the information regarding the empty slot in which the semiconductor wafer is not loaded to the dummy transferring robot to allow the dummy transferring robot to load a dummy wafer into the empty slot of the wafer guide into which the semiconductor wafer has not been loaded.

4. The wet station of claim 1, further comprising a direction adjusting unit adjusting a direction of the semiconductor wafers such that the semiconductor wafers are arranged in a vertical direction with respect to a bottom surface of the wafer guide or the semiconductor wafers reloaded into the FOUP from the wafer guide are arranged in a horizontal direction with respect to the bottom surface of the wafer guide.

5. The wet station of claim 1, wherein the processing chamber includes a bath in which a wet etchant is accommodated and a drying chamber.

6. The wet station of claim 5, wherein the processing chamber further includes a transfer arm transferring the wafer guide to the bath and the drying chamber.

7. The wet station of claim 6, wherein the transfer arm reciprocates along a wafer transfer line disposed to be adjacent to the bath and the drying chamber.

8. The wet station of claim 5, wherein a plurality of baths are provided and include a chemical bath and a rinsing bath.

9. The wet station of claim 1, wherein the loading unit includes a prop on which the FOUP and the stocker are supportedly placed.

10. The wet station of claim 1, further comprising a controller controlling driving of the loading unit, the wafer transferring robot, the dummy transferring robot, and the processing chamber.

11. The wet station of claim 1, wherein the wafer transferring robot reloads the plurality of semiconductor wafers having completely undergone the cleaning process from the wafer guide to the FOUP.

12. The wet station of claim 1, wherein the dummy transferring robot reloads the dummy wafers which have been completely undergone the cleaning process from the wafer guide to the stocker.

13. A wet station, comprising:
a wafer transferring robot removing semiconductor wafers from a front open unified pod (FOUP) in which the semiconductor wafers are installed and loading the semiconductor wafers into a wafer guide;
a dummy transferring robot removing dummy wafers from a stocker in which the dummy wafers are installed and loading the dummy wafers into empty slots of the wafer guide to which the semiconductor wafers have not been loaded; and
a controller controlling operations of the wafer transferring robot and the dummy transferring robot by sensing the semiconductor wafers loaded in the FOUP by means of a sensor.

14. The wet station of claim 13, wherein the sensor transfers information regarding empty slots to which the semiconductor wafers have not been loaded to the dummy transferring robot to allow the dummy transferring robot to load the dummy wafers into the empty slots of the wafer guide to which the semiconductor wafers have not been loaded.

15. The wet station of claim 13, further comprising a processing chamber receiving the wafer guide fully loaded with the semiconductor wafers and the dummy wafers and performing a cleaning process on the semiconductor wafers.
